(19) United States
(12) Patent Application Publication
(10) Pub. No.: US 2015/0079764 A1
(43) Pub. Date: Mar. 19, 2015

(54) VAPOR PHASE GROWTH APPARATUS AND VAPOR PHASE GROWTH METHOD

(71) Applicant: Kabushiki Kaisha Toshiba, Tokyo (JP)

(72) Inventor: Katsuhiko Nishitani, Kanagawa-ken (JP)

(73) Assignee: Kabushiki Kaisha Toshiba, Tokyo (JP)

(21) Appl. No.: 14/202,137

(22) Filed: Mar. 10, 2014

(30) Foreign Application Priority Data
Sep. 13, 2013 (JP) 2013-191116

(51) Int. Cl. H01L 21/687; H01L 21/02

(52) U.S. Cl. CPC H01L 21/6875; H01L 21/0262
USPC 438/478; 118/730

(57) ABSTRACT

According to one embodiment, a vapor phase growth apparatus includes a susceptor in a chamber, the susceptor configured to rotate on an axis perpendicular to a surface of the susceptor, a plurality of substrate holding portions above the susceptor, each of the substrate holding portions configured to revolve around the axis by the rotation of the susceptor and configured to rotate circumferentially, a plurality of bearings arranged in a housing between the susceptor and the substrate holding portion, and a plurality of blade portions on an outer periphery of the substrate holding portion, each of the blade portions extending radially toward a center of the substrate holding portion.

### CROSS-REFERENCE TO RELATED APPLICATION

This application is based upon and claims the benefit of priority from Japanese Patent Application No. 2013-191116, filed Sep. 13, 2013; the entire contents of which are incorporated herein by reference.

### FIELD

Embodiments described herein relate generally to a vapor phase growth apparatus and a vapor phase growth method.

### BACKGROUND

A vapor phase growth apparatus used for the fabrication of semiconductor devices such as a light emitting device and a High Electron Mobility Transistor (HEMT) is one of important apparatuses when a high quality film is formed. Particularly, in an apparatus for performing metal organic chemical vapor deposition (MOCVD), a multitude of wafers may be processed at a time for the purpose of mass production. In a vapor phase growth apparatus, a plurality of substrate holding portions is provided on a susceptor on which a wafer is arranged. Film formation may be performed on a multitude of wafers at a time by arranging a wafer on each of a plurality of substrate holding portions.

The susceptor has a rotating mechanism in order to perform uniform film formation on a plurality of wafers on the susceptor. Further, each of the substrate holding portions on the susceptor also has a rotating mechanism. The substrate holding portion is rotatably supported on the susceptor through a bearing. In the vapor phase growth apparatus, when raw-material gas flows into the housing of the bearing, and deposit adheres to the surface of the bearing, the rotation of the substrate holding portion is affected. In the vapor phase growth apparatus, it is important to keep the function of the bearing for a long time.

### DESCRIPTION OF THE DRAWINGS

FIG. 1A and FIG. 1B are schematic block diagrams illustrating a configuration of a vapor phase growth apparatus according to a first embodiment.

FIG. 2A and FIG. 2B are schematic cross-sectional views illustrating a configuration of a substrate holding portion according to the first embodiment.

FIG. 3A and FIG. 3B are schematic plane views illustrating a configuration of the substrate holding portion and a configuration of a tray portion, respectively, according to the first embodiment.

FIG. 4A and FIG. 4B are schematic plane views illustrating a shape of a blade portion according to the first embodiment.

FIG. 5A and FIG. 5B are schematic cross-sectional views illustrating a configuration of a vapor phase growth apparatus according to a second embodiment.

FIG. 6A and FIG. 6B are schematic cross-sectional views illustrating each configuration of non-contact sealing members according to the second embodiment.

FIG. 7 is a flowchart illustrating a vapor phase growth method according to a third embodiment.

### DETAILED DESCRIPTION

It is an object of an exemplary embodiment of the present disclosure to provide a vapor phase growth apparatus and a vapor phase growth method capable of maintaining function of a bearing that supports a substrate holding portion for a long time.

According to one embodiment, a vapor phase growth apparatus includes a susceptor in a chamber, the susceptor configured to rotate on an axis perpendicular to a surface of the susceptor, a plurality of substrate holding portions above the susceptor, each of the substrate holding portions configured to revolve around the axis by the rotation of the susceptor and configured to rotate circumferentially, a plurality of bearings arranged in a housing between the susceptor and the substrate holding portion, and a plurality of blade portions on the outer periphery of the substrate holding portion, each of the blade portions extending radially from the center of the substrate holding portion.

According to another embodiment, a vapor phase growth apparatus includes a susceptor in a chamber, the susceptor configured to rotate on an axis perpendicular to a surface of the susceptor, a plurality of substrate holding portions above the susceptor, each of the substrate holding portions configured to revolve around the axis by the rotation of the susceptor and configured to rotate circumferentially, a plurality of bearings arranged in a housing between the susceptor and the substrate holding portion, and a non-contact sealing portion including a part of susceptor, a part of the substrate holding portion, and a gap between the substrate holding portion and the susceptor and provided outside the housing.

Exemplary embodiments of the present disclosure will be described below with reference to the accompanying drawings. In the following description, the same symbols are assigned to the same elements and their description is not repeated as appropriate.

### First Embodiment

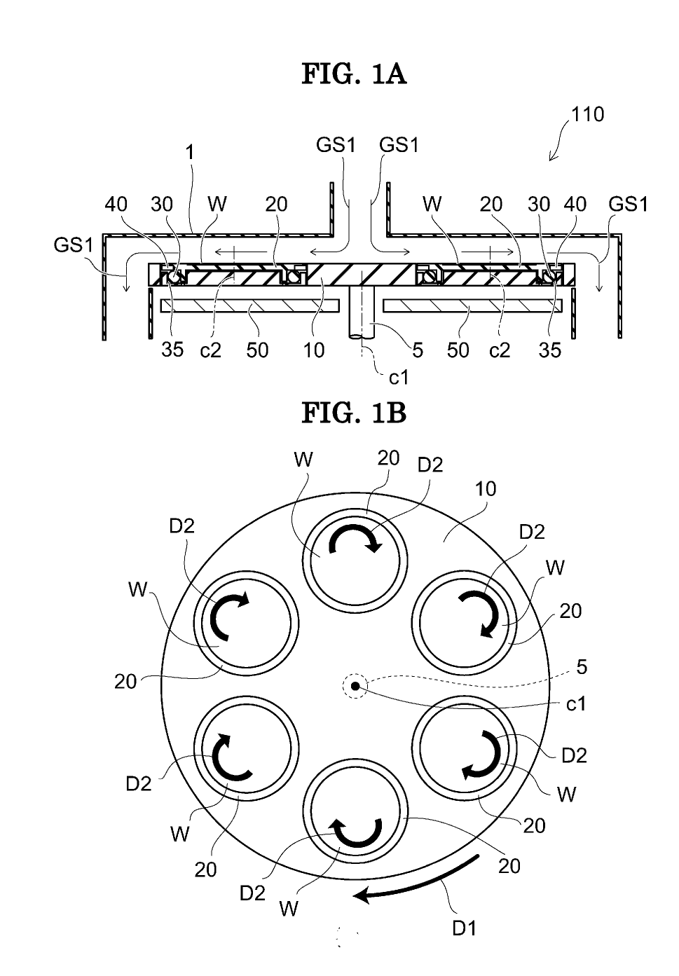

FIG. 1A and FIG. 1B are schematic block diagrams illustrating a configuration of a vapor phase growth apparatus according to a first embodiment. FIG. 1A shows a schematic cross-sectional view of a vapor phase growth apparatus 110 according to the present embodiment. FIG. 1B shows a schematic plan view of a susceptor 10 and a substrate holding portion 20.

As shown in FIG. 1A, the vapor phase growth apparatus 110 according to the present embodiment includes the susceptor 10, the substrate holding portion 20, a plurality of bearings 30 and a plurality of blade portions 40. The vapor phase growth apparatus 110 is an MOCVD apparatus, for example.

The vapor phase growth apparatus 110 further includes a chamber 1 and a heater 50. The susceptor 10 rotates around an axis c1 in the chamber 1. As shown in FIG. 1B, the susceptor 10 is disk-like, for example, and a rod-like support member 5 is attached to the center of the disk. The axis c1 represents the axial center of the support member 5. The susceptor 10 is rotated around the axis c1 in a circumferential direction D1 by a driver, not shown.

The substrate holding portion 20 is provided on the susceptor 10. In examples shown in FIG. 1A and FIG. 1B, the plurality of substrate holding portions 20 are provided. A plurality of substrate holding portions 20 is arranged on the susceptor 10 on a circumference of centered on the axis c1 at regular intervals. The substrate holding portion 20 is disk-like, for example. Each of the plurality of the substrate holding portions 20 rotates in a circumferential direction D2 along a surface perpendicular to the axis c1 on the susceptor 10. The rotation of the substrate holding portion 20 includes the revolution caused by the rotation of the susceptor 10 and the rotation of the substrate holding portion 20.

A gear, not shown, is provided on the outer periphery of the disk-like substrate holding portion 20. The gear of the substrate holding portion 20 engages with a gear provided inside a ring member, not shown, that is arranged so as to surround the outer periphery of the susceptor 10. When the substrate holding portion 20 revolves caused by the rotation of the susceptor 10, the gear of the substrate holding portion 20 engages with the gear of the ring member, thus the substrate holding portion 20 rotates on its axis.

The bearings 30 are arranged in a housing 35 provided between the susceptor 10 and the substrate holding portion 20. The bearings 30 are arranged near the outer periphery of substrate holding portion 20 on the side of the susceptor 10. The substrate holding portion 20 is put on the bearings 30. In this manner, the substrate holding portion 20 rotates smoothly on the susceptor 10 by the rolling action of the bearings 30. For example, a wafer W to be processed is provided on the surface of the substrate holding portion 20.

The blade portions 40 are provided on the outer periphery of the substrate holding portion 20. Each of the blades 40 includes a portion extending radially from the center of the substrate holding portion 20.

In order to perform vapor phase growth using the vapor phase growth apparatus 110, first, a wafer W is put on the substrate holding portion 20 on the susceptor 10, and the susceptor 10 and the substrate holding portion 20 are rotated. Then, the wafer W is heated by the heater 50. And then, a raw-material gas GS1 is introduced in the chamber 1. In this manner, the raw-material gas GS1 reacts on the heated wafer W, and a film having prescribed composition is formed according to the component of the raw-material gas.

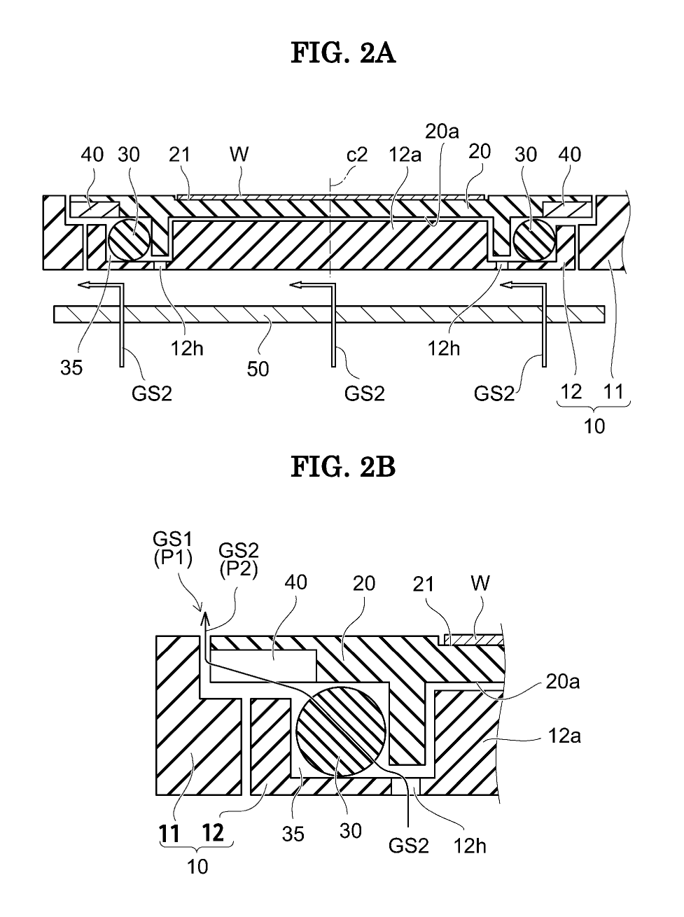

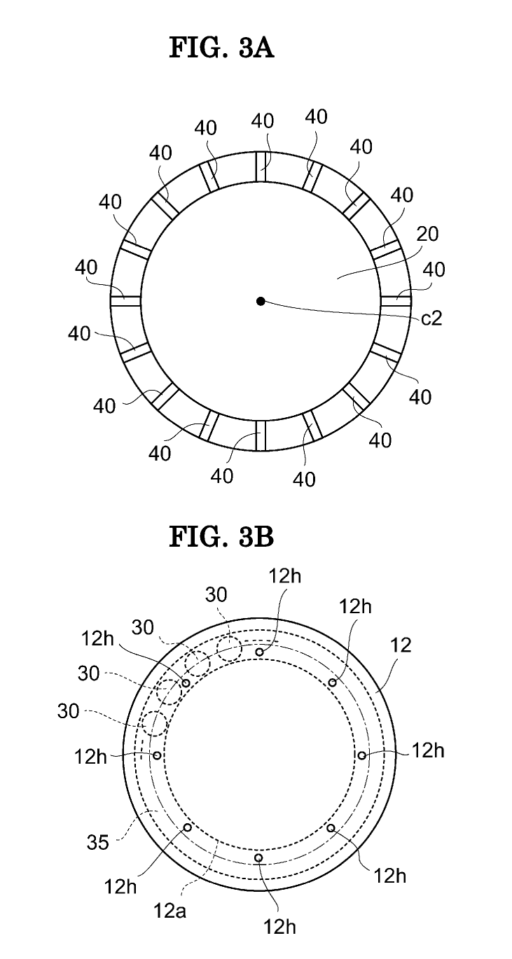

FIG. 2A and FIG. 2B are schematic cross-sectional views illustrating a configuration of a substrate holding portion. FIG. 2A shows a schematic cross-sectional view of the entire substrate holding portion 20, and FIG. 2B shows a schematic cross-sectional view of the enlarged outer periphery of the substrate holding portion 20. FIG. 3A and FIG. 3B are schematic plane views illustrating a configuration of the substrate holding portion and a tray portion. FIG. 3A shows a schematic plane view of the substrate holding portion 20 viewed from a tray portion 12 side (bottom side). FIG. 3B shows a schematic plan view of the tray portion 12 viewed from the opposite side (bottom side) to the substrate holding portion 20.

As shown in FIG. 2A, the susceptor 10 includes a body portion 11 and the tray portion 12. The tray portion 12 is provided on the bottom side of the substrate holding portion 20. The tray portion 12 is inserted into a hole in the body portion 11. The substrate holding portion 20 is arranged on the tray portion 12.

A depressed portion 20a is provided in the center of the substrate holding portion 20. On the other hand, a projecting portion 12a is provided in the center of the tray portion 12. The depressed portion 20a in the substrate holding portion 20 is put on the projecting portion 12a in the tray portion 12. The inner diameter of the depressed portion 20a is slightly larger than the contour of the projecting portion 12a.

Further, a housing 35 of the bearing 30 is provided between the substrate holding portion 20 and the tray portion 12. The housing 35 is provided on the tray portion 12 side on the outer periphery of the substrate holding portion 20. The housing 35 surrounds the outside of the projecting portion 12a in the tray portion 12. The predetermined number of the bearings 30 is arranged in the housing 35. For example, the bearings 30 are arranged on the circumference through the center of the housing 35 by a ratio of approximately 60% to 80% of the circumference.

The diameter of each of the bearings 30 is slightly larger than a height of the projecting portion 12a in the tray portion 12. Therefore, when the bearings 30 are arranged on the housing 35, and the substrate holding portion 20 is put on the tray portion 12, the substrate holding portion 20 is supported by the bearings 30. When the substrate holding portion 20 is arranged on the tray portion 12 through the bearings 30, a gap is provided between the inner surface of the depressed portion 20a and the outer surface of the projecting portion 12a. This gap allows the substrate holding portion 20 to rotate smoothly on the tray portion 12 by the rolling action of the bearing 30.

A step 21 is provided on the opposite side (surface side) to the tray portion 12 of the substrate holding portion 20. A wafer W is put on the step 21.

An introduction opening 12h for counter gas GS2 is provided in the tray portion 12. Inert gas such as N₂ is used for the counter gas GS2. The counter gas GS2 inhibits the gas GS1 for growth introduced in the chamber 1 from flowing into the bottom of the susceptor 10.

The introduction opening 12h is a through-hole that reaches the housing 35 of the bearing 30 from the outer peripheral surface (e.g., underside) of the tray portion 12. As shown in FIG. 3B, a plurality of introduction openings 12h are provided at predetermined intervals along the circumference slightly inside from the outer periphery of the tray portion 12. It is desirable that the introduction opening 12h is arranged inside or outside to the center of the bearing 30 arranged in the housing 35. This prevents the introduction opening 12h from being blocked by the bearings 30.

As shown in FIG. 3A, the blade portions 40 are provided on the outer periphery of the substrate holding portion 20. Each of the blade portions 40 has a portion extending radially from the center c2 of the substrate holding portion 20. The example shown in FIG. 3A represents each of the blade portions 40 radially extending on a straight line from the center c2 of the substrate holding portion 20.

When such blade portions 40 are provided, and the substrate holding portion 20 rotates (on its axis), a pressure on the side of the housing 35 centered on the substrate holding portion 20 becomes higher than a pressure on the opposite side to the housing 35. That is, the rotation of the blade portions 40 generates the pressure difference between the front side and the back side of the substrate holding portion 20.

As shown in FIG. 2B, the pressure difference generated by the rotation of the blade portions 40 causes the counter gas GS2 introduced from the introduction opening 12h to flow from the housing 35 to the front side of the substrate holding portion 20 through the gap between each of the blade portions 40 and the body portion 11 of the susceptor 10.

When vapor phase growth is performed by the vapor phase growth apparatus 110, the raw-material gas GS1 is sent into the front side of the substrate holding portion 20. Here, assuming that the pressure generated by the raw-material gas GS1 flowing from the surface of the substrate holding portion 20 toward the housing 35 is set to be P1, and the pressure generated by the counter gas GS2 flowing from the housing 35 toward the surface of the substrate holding portion 20 is set to be P2 in the gap between the blade portion 40 and the body portion 11 of the susceptor 10, the blade portions 40 are provided so that the pressure P2 becomes higher than the pressure P1. This inhibits the raw-material gas GS1 from flowing into the housing 35 of the bearing 30 during vapor phase growth processing.

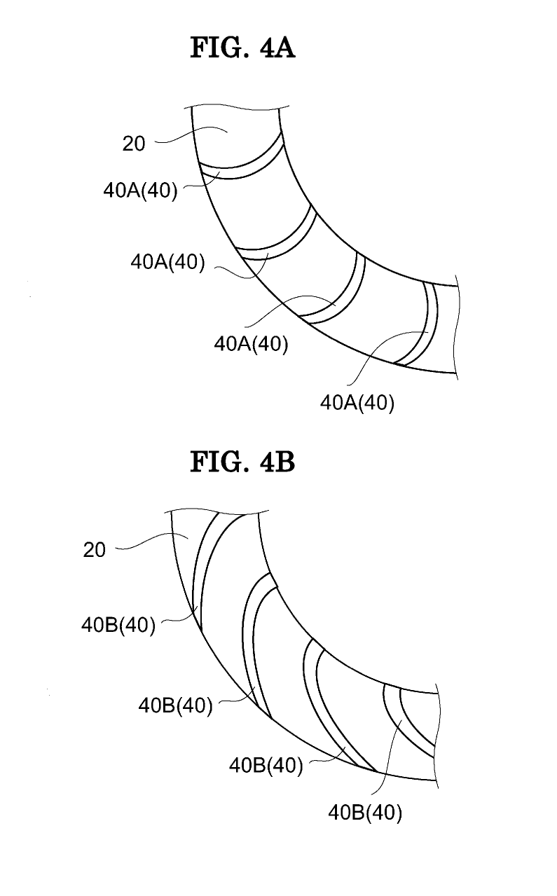

FIG. 4A and FIG. 4B are schematic plan views illustrating shapes of another blade portions. FIG. 4A shows a schematic plane view of a plurality of blade portions 40A. FIG. 4B shows a schematic plane view of a plurality of blade portions 40B. Each of the blades 40A shown in FIG. 4A is curved. Each of the blade portions 40B is tilted with respect to the radial direction. Each of blade portions 40A and 40B has a portion extending radially. Various types of blade portions 40 may be used, including a turbo type, a sirocco type and a radial type. The size, shape and the number of the blade portions 40 are suitably determined depending on the size and the rotational frequency of the substrate holding portion 20, and the relation between the pressures P1 and P2.

The vapor phase growth apparatus 110 according to the present embodiment inhibits the raw-material gas GS1 from flowing into the housing 35 of the bearing 30 due to generation of pressure difference by the blade portions 40, and inhibits deposit due to the raw-material gas GS1 from adhering to the surface of the bearing 30.

### Second Embodiment

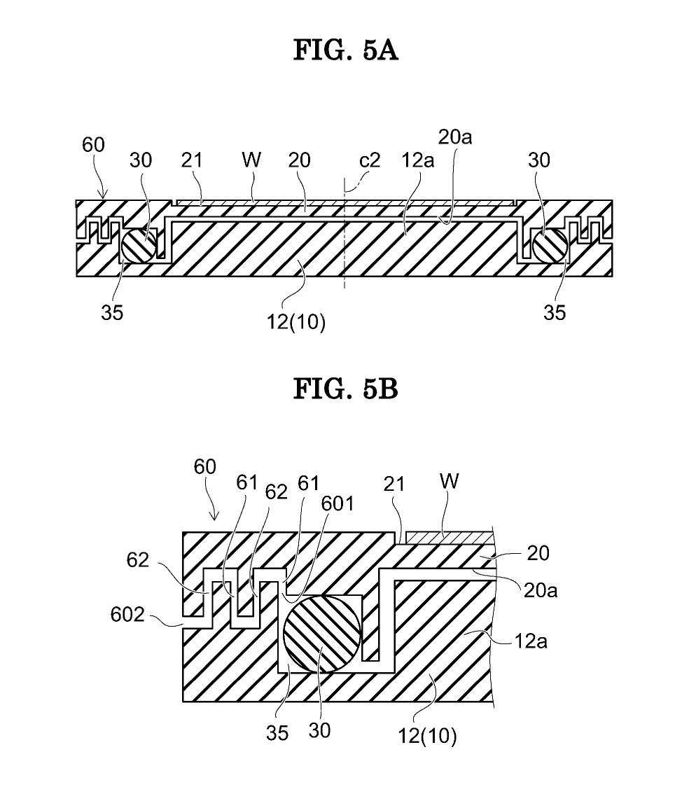

Next, a vapor phase growth apparatus according to a second embodiment will be described. FIG. 5A and FIG. 5B are schematic cross-sectional views illustrating a configuration of a vapor phase growth apparatus according to the second embodiment. FIG. 5A shows a schematic cross-sectional view of the enlarged susceptor 10 and substrate holding portion 20 of a vapor phase growth apparatus 120 according to the second embodiment. FIG. 5B shows a schematic cross-sectional view of the enlarged outer periphery of the substrate holding portion 20. The configurations of the substrate holding portion 20 and the tray portion 12 (susceptor 10) on the side of the outer periphery than the housing 35 in the vapor phase growth apparatus 120 according to the second embodiment are different from those in the vapor phase growth apparatus 110 according to the first embodiment. Since other configurations in the vapor phase growth apparatus 120 are similar to those in the vapor phase growth apparatus 110, description thereof is omitted.

As shown in FIG. 5A, the vapor phase growth apparatus 120 according to the present embodiment includes a non-contact sealing member 60. The non-contact sealing member 60 is provided between the substrate holding portion 20 and the tray portion 12 and outside the housing 35 of the bearings 30.

In the vapor phase growth apparatus 120, the non-contact sealing member 60 inhibits raw-material gas GS1 from flowing into the housing 35 of the bearings 30 through the gap between the substrate holding portion 20 and the tray portion 12.

As shown in FIG. 5B, the non-contact sealing member 60 includes, for example, a labyrinth seal. The labyrinth seal produces a labyrinth effect by forming a gap between the substrate holding portion 20 and the tray portion 12 into a labyrinth configuration.

In the non-contact sealing member 60, the gap between the substrate holding portion 20 and the tray portion 12 includes a first portion 61 and a second portion 62. The first portion 61 extends from a position 601 in communication with the housing 35 toward the substrate holding portion 20 (upper side). The second portion 62 extends toward the tray portion 12 side than the closest position to the substrate holding portion 20 in the first portion 61. That is, the first portion 61 rises up from the position 601 in communication with the housing 35. The second portion 62 falls down from the uppermost position of the first portion 61. There may be another portion (e.g., a portion where height does not change) between the first portion 61 and the second portion 62.

In the example shown in FIG. 5B, a plurality of first portions 61 and a plurality of second portions 62 are provided alternately. The more the number of the first portions 61 and the second portions 62 increases, the more the labyrinth effect increases.

In addition, it is desirable that, in the gap between the substrate holding portion 20 and the tray portion 12, the outermost position 602 in the non-contact sealing member 60 is separated from the surface side (the side where a wafer W is put on) of the substrate holding portion 20. When the position 602 is near to the surface of the substrate holding portion 20, the raw-material gas GS1 is likely to enter from the front side of the substrate holding portion 20. It is desirable that the position 602 is separated from the surface of the substrate holding portion 20 in order to enhance the sealing effect of the raw-material gas GS1. For example, the position 602 is provided on the side of the tray portion 12 than the position 601.

When vapor phase growth is performed by the vapor phase growth apparatus 120, the raw-material gas GS1 is sent into the front side of the substrate holding portion 20. Then, a wafer W is put on the substrate holding portion 20, and the susceptor 10 and the substrate holding portion 20 are rotated. The rotation of the substrate holding portion 20 generates a labyrinth effect in the non-contact sealing member 60. The labyrinth effect inhibits the raw-material gas GS1 from flowing into the housing 35.

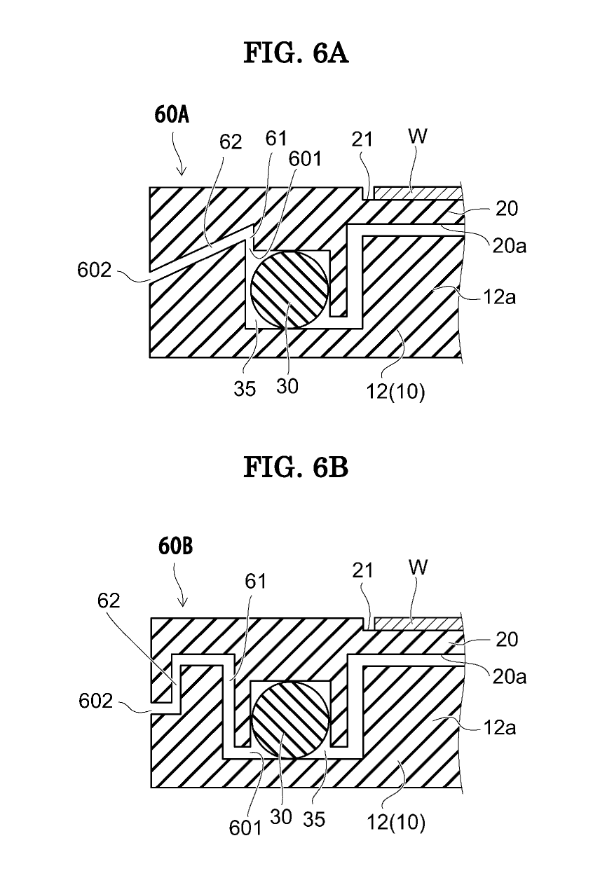

FIG. 6A and FIG. 6B are schematic cross-sectional views illustrating a configuration of other non-contact sealing members. In a non-contact sealing member 60A shown in FIG. 6A, the second portion 62 extends diagonally downward. That is, the first portion 61 extends upward from the position 601 of the housing 35. The second portion 62 goes diagonally downward from the uppermost position of the first portion 61 and then extends linearly to the position 602.

In a non-contact sealing member 60B shown in FIG. 6B, the position 601 in the gap in communication with the housing 35 is provided on the underside of the housing 35. In the non-contact sealing member 60, the first portion 61 goes upward from the position 601 on the underside of the housing 35 and extends to the upper position than the housing 35. The second portion 62 extends downward from the uppermost position of the first portion 61.

Note that the configuration of the non-contact sealing member 60 is not limited to the examples shown in FIG. 5A to FIG. 6B.

In the vapor phase growth apparatus 120 according to the present embodiment, such a sealing effect by the non-contact sealing member 60 can inhibit the raw-material gas GS1 from flowing into the housing 35 of the bearing 30, thus, inhibiting deposit due to the raw-material gas GS1 from adhering to the surface of the bearing 30.

### Third Embodiment

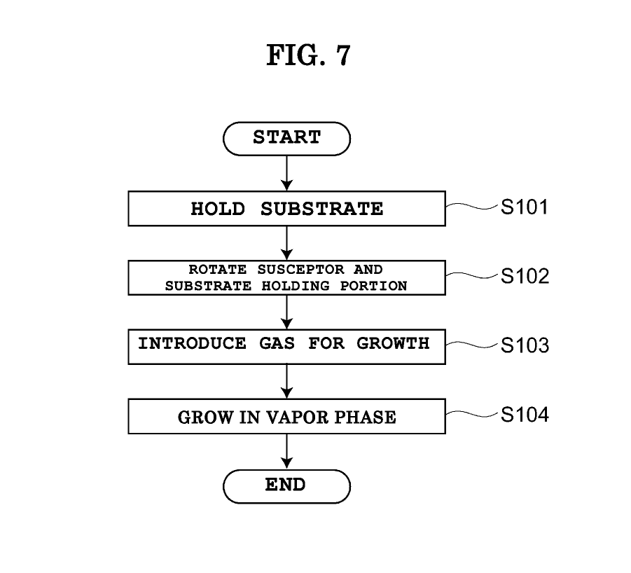

Next, a vapor phase growth method according to a third embodiment will be described. FIG. 7 is a flowchart illustrating the vapor phase growth method according to the third embodiment. The vapor phase growth method according to the present embodiment performs vapor phase growth using the vapor phase growth apparatuses 110 and 120 described above.

As shown in FIG. 7, the vapor phase growth method according to the present embodiment includes holding a wafer (step S101), rotating a susceptor and a substrate holding portion (step S102), introducing raw-material gas (step S103) and forming a film (step S104).

In step S101, the wafer W is put on the substrate holding portion 20 on the susceptor 10. As the wafer W, a GaN substrate, a sapphire substrate, a SiC substrate, a GaAs substrate and an Si substrate may be used.

Next, in step S102, the susceptor 10 is rotated and the substrate holding portion 20 is also rotated. The substrate holding portion 20 revolves caused by the rotation of the susceptor 10, and rotates on its axis with respect to the susceptor 10. The wafer W also revolves and rotates on the axis thereof caused by the revolution and rotation of the substrate holding portion 20. Next, while the susceptor 10 and the substrate holding portion 20 are being rotated, the wafer W is heated by the heater 50. The heating temperature is between 600 degrees Celsius and 1,300 degrees Celsius, for example.

Next, in step S103, raw-material gas GS1 is introduced in the chamber 1. As gas GS1 for growth, for example, organic metal gas is used. As the raw-material gas GS1, trimethyl gallium (TMGa), trimethyl indium (TMI), aluminum trimethyl (TMA), silane (SiH₄), arsine (AsH₃), phosphine (PH₃), ammoniacal (NH₃) and the like are used. Note that N₂ and H₂ are used for carrier gas, for example.

For example, when semiconductor devices such as a Light Emitting Diode (LED), a Laser Diode (LD) and an HEMT are manufactured, TMI, TMG, TMA, SiH₄ and NH₃ are used to perform vapor phase growth of the GaN-based film, and TMI, TMG, TMA, SiH₄, AsH₃ and PH₃ are used to perform vapor phase growth of the GaAs-based film.

Further, in step S103, the counter gas GS2 may be introduced in addition to the introduction of the gas GS1 for growth. Inert gas such as N₂ is used for the counter gas GS2.

Next, in step S104, a film is formed on the surface of the wafer W in the chamber 1. That is, the raw-material gas GS1 introduced in the chamber 1 reacts on the surface of the wafer W to achieve the crystal growth of the film according to the material of the raw-material gas GS1 on the surface of the wafer W.

When the vapor phase growth apparatus 110 is used in the vapor phase growth method according to the present embodiment, by the rotation of the blade portions 40 caused by the rotation of the substrate holding portion 20, the pressure on the side of the housing 35 centered on the substrate holding portion 20 becomes higher than the pressure on the opposite side to the housing 35. This inhibits the raw-material gas GS1 from entering into the housing 35 during film formation, and also inhibits the counter-flow of the counter gas GS2.

When the vapor phase growth apparatus 120 is used in the vapor phase growth method according to the present embodiment, for example, pressure difference due to a labyrinth effect is generated between the inside of the housing 35 and the outside of the housing 35 by the rotation of the substrate holding portion 20. This inhibits the raw-material gas GS1 from entering into the housing 35 during film formation.

Using such a vapor phase growth method, the semiconductor devices including a light emitting device such as an LED, an HEMT and a power transistor are manufactured.

The vapor phase growth method according to the present embodiment effectively inhibits the raw-material gas GS1 from entering into the housing 35 of the bearing 30. This inhibits deposit due to the raw-material gas GS1 from adhering to the surface of the bearing 30. That is, inhibiting deposit from adhering to the surface of the bearing 30 reduces the interruption and stopping of the operation of the apparatus caused by the trouble of the bearing 30. Thus, semiconductor devices having high quality can be manufactured productively.

As described above, according to the vapor phase growth apparatus and the vapor phase growth method according to the embodiments, the function of the bearing 30 that supports the substrate holding portion 20 can be maintained for a long time.

Note that although the present embodiment and variations thereof have been described, the present disclosure is not limited to these exemplary embodiments. For example, an MOCVD is taken as an example for the vapor phase growth apparatuses 110 and 120, but a CVD other than an MOCVD can be applicable. In addition, addition, deletion and change of a configuration may be suitably made by those skilled in the art on each embodiment and variation described above, and features of each embodiment may be suitably combined, which are encompassed in the present disclosure, without departing from the spirit of the disclosure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A vapor phase growth apparatus comprising:
a susceptor in a chamber configured to rotate on an axis perpendicular to a surface of the susceptor;
a plurality of substrate holding portions above the susceptor, each of the substrate holding portions configured to revolve around the axis by the rotation of the susceptor and configured to rotate circumferentially;
a plurality of bearings which are arranged in a housing between the susceptor and the substrate holding portion; and
a plurality of blade portions on the outer periphery of the substrate holding portion, each of the blade portions extending radially toward a center of the substrate holding portion.

2. The vapor phase growth apparatus according to claim 1, wherein
the susceptor is provided with openings reaching the housing.

3. The vapor phase growth apparatus according to claim 1, wherein
the plurality of blade portions has one of a linear shape, a curved shape and a tilted shape to the susceptor.

4. The vapor phase growth apparatus according to claim 1, wherein
the plurality of the blade portions has one of a turbo type, a sirocco type and a radial type.

5. A vapor phase growth apparatus comprising:
a susceptor in a chamber, the susceptor configured to rotate on an axis perpendicular to a surface of the susceptor;
a plurality of substrate holding portions above the susceptor, each of the substrate holding portions configured to revolve around the axis by the rotation of the susceptor and configured to rotate circumferentially;
a plurality of bearings arranged in a housing between the susceptor and the substrate holding portion; and
a non-contact sealing portion including a part of susceptor, a part of the substrate holding portion, and a gap between the substrate holding portion and the susceptor and provided outside the housing.

6. The vapor phase growth apparatus according to claim 5, wherein
the non-contact sealing portion includes a labyrinth seal.

7. The vapor phase growth apparatus according to claim 5, wherein
the gap between the susceptor and the substrate holding portion in the non-contact sealing portion includes:
a first portion extending from a position in communication with the housing toward the substrate holding portion, and
a second portion extending toward the susceptor side from the closest position to the substrate holding portion in the first portion.

8. The vapor phase growth apparatus according to claim 7, wherein
a third portion is connected between the first portion and the second portion.

9. The vapor phase growth apparatus according to claim 8, wherein
the third portion has a constant height.

10. The vapor phase growth apparatus according to claim 8, wherein
the outmost position in the non-contact sealing member has the longest distance from a surface side of the substrate holding portion in the non-contact sealing member.

11. The vapor phase growth apparatus according to claim 7, wherein
the second portion extends diagonally down ward.

12. The vapor phase growth apparatus according to claim 7, wherein
the first portion goes upward from a position on an underside of the housing.

13. A vapor phase growth method which uses a vapor phase growth apparatus including a susceptor in a chamber, the susceptor configured to rotate on an axis perpendicular to a surface of the susceptor, a plurality of substrate holding portions above the susceptor, each of the substrate holding portions configured to revolve around the axis by the rotation of the susceptor and configured to rotate circumferentially, a plurality of bearings which are arranged in a housing between the susceptor and the substrate holding portion, and a plurality of blade portions on an outer periphery of the substrate holding portion, each of the blade portions extending radially toward a center of the substrate holding portion, the method comprising:
holding a substrate by the substrate holding portion;
rotating the susceptor and the substrate holding portion;
introducing raw-material gas into the chamber; and
forming a film made from the raw-material gas on a surface of the substrate.

14. The vapor phase growth method according to claim 13, wherein
the introducing the raw-material gas includes introducing counter gas from the outer peripheral surface of the susceptor to the housing.

15. The vapor phase growth method according to claim 13, wherein
the rotating the susceptor and the substrate holding portion includes rotating a plurality of blades caused by the rotation of the substrate holding portion so that pressure on the side of the housing centered on the substrate holding portion becomes higher than pressure on the opposite side to the housing to inhibit counter-flow of the counter gas.

16. A vapor phase growth method which uses a vapor phase growth apparatus including a susceptor in a chamber, the susceptor configured to rotate on an axis perpendicular to a surface of the susceptor, a plurality of substrate holding portions above the susceptor, each of the substrate holding portions configured to revolve around the axis by the rotation of the susceptor and configured to rotate circumferentially, a plurality of bearings arranged in a housing between the susceptor and the substrate holding portion,
and a non-contact sealing portion including a part of susceptor, a part of the substrate holding portion, and a gap between the substrate holding portion and the susceptor and provided outside the housing, comprising:
holding a substrate by the substrate holding portion;
rotating the susceptor and the substrate holding portion;
introducing raw-material gas into the chamber; and
forming a film made from the raw-material gas on a surface of the substrate.

17. The vapor phase growth method according to claim 16, wherein
the non-contact sealing portion includes a labyrinth seal, and
rotating the susceptor and the substrate holding portion includes generating a labyrinth effect between the inside of the housing and the outside of the housing by the rotation of the substrate holding portion.
